(19) United States
(12) Patent Application Publication
(10) Pub. No.: US 2010/0026173 A1
(43) Pub. Date: Feb. 4, 2010

(54) METHOD OF DEPOSITING LIGHT EMITTING LAYER OF ORGANIC EL DEVICE, METHOD OF MANUFACTURING ORGANIC EL DEVICE, AND ORGANIC EL DEVICE MANUFACTURED BY THE METHOD

(75) Inventors: Za-Il Lhee, Yongin-City (KR); Sang-Mok Hong, Yongin-City (KR); Keun-Soo Lee, Yongin-City (KR)

Correspondence Address: KNOBBE MARTENS OLSON & BEAR LLP, 2040 MAIN STREET, FOURTEENTH FLOOR, IRVINE, CA, 92614, US

(73) Assignee: Samsung Mobile Display Co., Ltd., Yongin-City (KR)

(21) Appl. No.: 12/508,492

(22) Filed: Jul. 23, 2009

(30) Foreign Application Priority Data
Aug. 4, 2008 (KR) 10-2008-0076111

(51) Int. Cl. H01J 1/62; H01J 9/00; B05D 5/06

(52) U.S. Cl. 313/504; 445/24; 427/66

(57) ABSTRACT

A method of depositing a light emitting layer of an organic EL device in which a subpixel combination having a plurality of different colors is set as a unit pixel, a plurality of subpixels are sequentially and alternately arranged in a row direction, and a plurality of subpixels of the same color are arranged in a column direction, includes first depositing the light emitting layer using a mask having a plurality of opening portions corresponding to positions of the subpixels of the same color arranged in any of an odd numbered row and an even-numbered column of the subpixels, and second depositing the light emitting layer by moving the mask to prevent the light emitting layer from being deposited at a subpixel adjacent to the subpixel where the light emitting layer is deposited during the first deposition operation, using the same opening portion of the mask used for the first deposition operation of the light emitting layer.

### CROSS-REFERENCE TO RELATED PATENT APPLICATIONS

This application claims the benefit of Korean Patent Application No. 10-2008-0076111, filed on Aug. 4, 2008, in the Korean Intellectual Property Office, the disclosure of which is incorporated herein in its entirety by reference.

### BACKGROUND

1. Field

The present embodiments relate to a method of depositing a light emitting layer of an organic electroluminescent (EL) device, a method of manufacturing an organic EL device including the above deposition method, and an organic EL device manufactured by the above manufacturing method.

2. Description of the Related Art

Organic EL devices that are active type light emitting display devices have drawn attention as one of next generation display devices because of a wide viewing angle, a superior contrast, and a fast response speed. The organic EL device is formed by forming an anode in a predetermined pattern on a glass or other transparent insulation substrate and then sequentially depositing an organic material and a cathode over the anode.

When a voltage is applied to the anode and the cathode of the organic EL device configured as above, a plurality of holes injected from the anode move toward a light emitting layer via a hole transport layer and a plurality of electrons generated by the cathode are injected in the light emitting layer by passing through an electron transport layer. In the light emitting layer, the electrons and the holes are combined and generate excitons. As the excitons move from an exciton state to a ground state, a plurality of organic molecules of the light emitting layer emit light to form an image.

To manufacture an organic EL device capable of presenting a full color scheme, a method of independently depositing subpixels of red (R), green (G), and blue (B) on a substrate using a mask, forming each unit pixel, is generally used. In forming a unit pixel of the organic EL device according to the above method, a slit type shadow mask or a slot type shadow mask is often used.

FIG. 1 is a plan view of a slit type unit mask 10. FIG. 2 is a plan view of a slot type unit mask 20. Referring to FIG. 1, the slit type unit mask 10 includes a shield portion 11 and an opening portion 12 in a strip shape. The slit type unit mask 10 is advantageous in that the opening portion 12 is large because the opening portion 12 corresponding to one of the subpixels of R, G, and B, for example, the subpixel R in FIG. 1, is open in a strip shape so that shadowing occurring between upper and lower pixels does not need to be considered. However, since there is no cross rib between the upper and lower pixels, the mask sags due to the weight thereof so that the substrate and the mask can be separated from each other. Furthermore, as the size of a display device increases, the size of the shadow mask increases as well so that the mask sagging phenomenon is deteriorated.

Referring to FIG. 2, the slot type unit mask 20 includes a shield portion 21 and an opening portion 22 having a slot shape corresponding to one of the subpixels of R, G, and B, for example, the subpixel R in FIG. 1. In the slot type unit mask 20, although the mask sagging phenomenon occurring in the slit type unit mask 10 is improved by a cross rib formed across the shield portion 21, the shadowing phenomenon due to the cross rib between the upper and lower pixels is generated so that the opening portion is narrowed.

### SUMMARY

The present embodiments provide a method of manufacturing an organic EL device which can prevent a mask sagging phenomenon, reduce the opening area, and improve visibility rate in a light emitting area.

According to an aspect of the present embodiments, there is provided a method of depositing a light emitting layer of an organic EL device in which a subpixel combination having a plurality of different colors is set as a unit pixel, a plurality of subpixels are sequentially and alternately arranged in a row direction, and a plurality of subpixels of the same color are arranged in a column direction, the method comprising: first depositing the light emitting layer using a mask having a plurality of opening portions corresponding to positions of the subpixels of the same color arranged in any of an odd-numbered row and an even-numbered column of the subpixels, and second depositing the light emitting layer by moving the mask to prevent the light emitting layer from being deposited at a subpixel adjacent to the subpixel where the light emitting layer is deposited during the first deposition operation, using the same opening portion of the mask used for the first deposition operation of the light emitting layer.

The subpixels may have different colors comprising red (R), green (G), and blue (B) subpixels.

The second deposition operation is performed by moving the mask aligned in the first deposition operation by a (2N+1) pixel pitch or more, where N is a natural number, in the column direction, that is, in directions of ±y.

The second deposition operation is performed by moving the mask aligned in the first deposition operation by a (2N−1) pixel pitch or more, where N is a natural number, in the column direction, that is, in directions of ±y, and by an N-pixel pitch or more, where N is a natural number, in the row direction, that is, in directions of ±x.

The second deposition operation is performed by rotating the mask aligned in the first deposition operation by 180° and moving the mask by a one-pixel pitch in the row direction, that is, in a direction of −x.

The second deposition operation is performed by rotating the mask aligned in the first deposition operation by 180° and moving the mask by a one-pixel pitch horizontally in the row direction, that is, in a direction of −x and by a one-pixel pitch vertically in the column direction, that is, in a direction of ±y.

The mask having the opening portions is used for independently depositing each of the subpixels of different colors.

The mask having the opening portions is a fine metal mask. According to another aspect of the present embodiments, there is provided a method of manufacturing an organic EL device, the method comprising forming a first electrode layer of a predetermine pattern on an insulating substrate, forming an organic light emitting layer comprising a light emitting layer of a predetermined pattern on the first electrode layer, forming a second electrode layer of a predetermined pattern on the organic light emitting layer, and sealing the outside of the second electrode layer, wherein, in the organic EL device in which a subpixel combination having a plurality of different colors is set as a unit pixel, a plurality of subpixels are sequentially and alternately arranged in a row direction, and a plurality of subpixels of the same color are arranged in a column direction, the forming of the organic light emitting layer comprises first depositing the light emitting layer using a mask having a plurality of opening portions corresponding to positions of the subpixels of the same color arranged in any of an odd-numbered row and an even-numbered column of the subpixels, and second depositing the light emitting layer by moving the mask to prevent the light emitting layer from being deposited at a subpixel adjacent to the subpixel where the light emitting layer is deposited during the first deposition operation, using the same opening portion of the mask used for the first deposition operation of the light emitting layer.

According to another aspect of the present embodiments, there is provided an organic EL device manufactured by the above method.

### BRIEF DESCRIPTION OF THE DRAWINGS

The above and other features and advantages of the present embodiments will become more apparent by describing in detail exemplary embodiments thereof with reference to the attached drawings in which:

FIG. 1 is a plan view of a slit type unit mask;

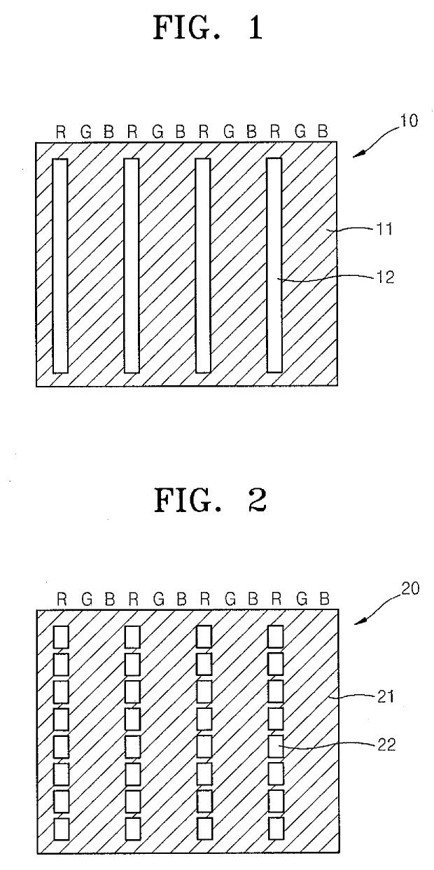

FIG. 2 is a plan view of a slot type unit mask;

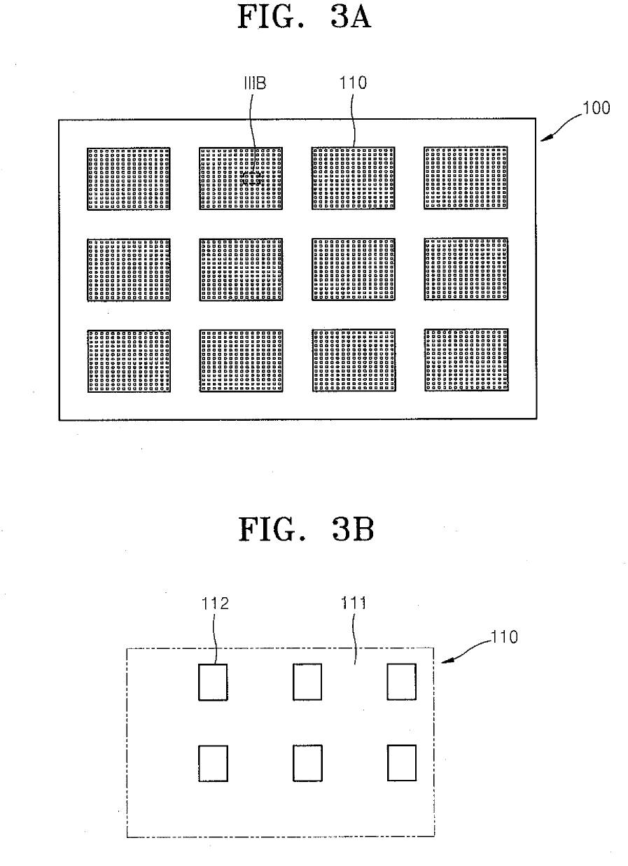

FIGS. 3A and 3B illustrate a mask for an organic EL device used in the present embodiments;

FIGS. 4A-4E illustrate a general method of depositing an organic light emitting layer of an organic EL device using the mask of FIGS. 3A and 3B;

FIGS. 5A and 5B are plan views for showing a method of depositing an organic light emitting layer of an organic EL device according to an embodiment, to reduce the inferior visibility due to a neighboring black spot;

FIGS. 6A and 6B are plan views for showing a method of depositing an organic light emitting layer of an organic EL device according to another embodiment, to reduce the inferior visibility due to a neighboring black spot;

FIGS. 7A and 7B are plan views for showing a method of depositing an organic light emitting layer of an organic EL device according to another embodiment, to reduce the inferior visibility due to a neighboring black spot; and

FIGS. 8A and 8B are plan views for showing a method of depositing an organic light emitting layer of an organic EL device according to a modified example of the embodiment of FIGS. 7A and 7B, to reduce the inferior visibility due to a neighboring black spot.

### DETAILED DESCRIPTION

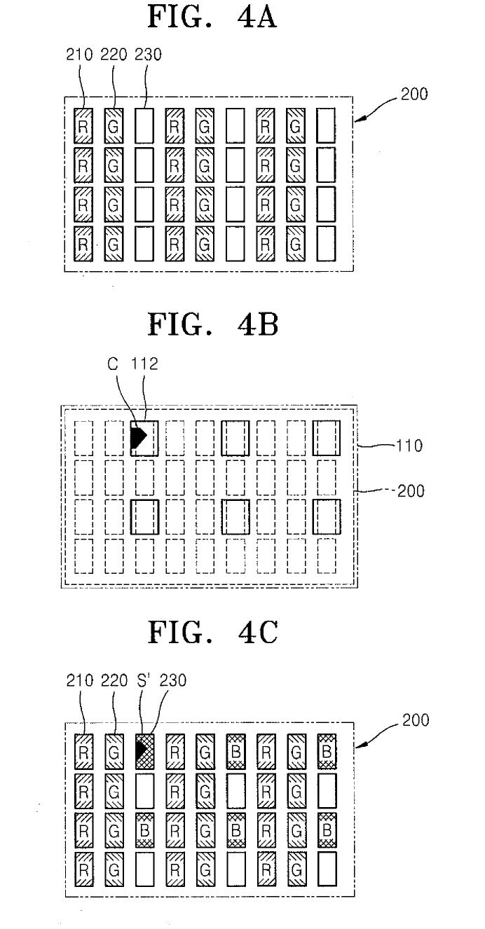

FIGS. 3A and 3B schematically illustrate a mask for an organic EL device used in the present embodiments. Referring to FIG. 3A, a mask 100 for an organic EL device used in the present embodiments includes at least one unit mask 110. Although twelve unit masks 110 are formed on the mask 100 that is a fine metal mask in the drawing, the present embodiments are not limited thereto and the number and arrangement of the unit masks 110 may be variously modified.

The unit mask 110 includes a shield portion 111 and a plurality of opening portions 112 that are patterned, as shown in FIG. 3B. Each of the opening portions 112, which will be described later, includes a plurality of subpixels arranged in a matrix type. In an organic EL device having subpixels of the same color in the same column, the opening portions 112 are formed to correspond to the positions of red (R), green (G), and blue (B) subpixels arranged in an odd-numbered column or an even-numbered row.

Since a rib is formed between upper and lower pixels in the mask 100, a mask sagging phenomenon is improved. Also, since the operation portions 112 are not formed continuously in the neighboring upper and lower pixels, a shadowing phenomenon between the upper and lower pixels is reduced so that a problem related to narrowing of the opening portion of the conventional slot type mask can be prevented.

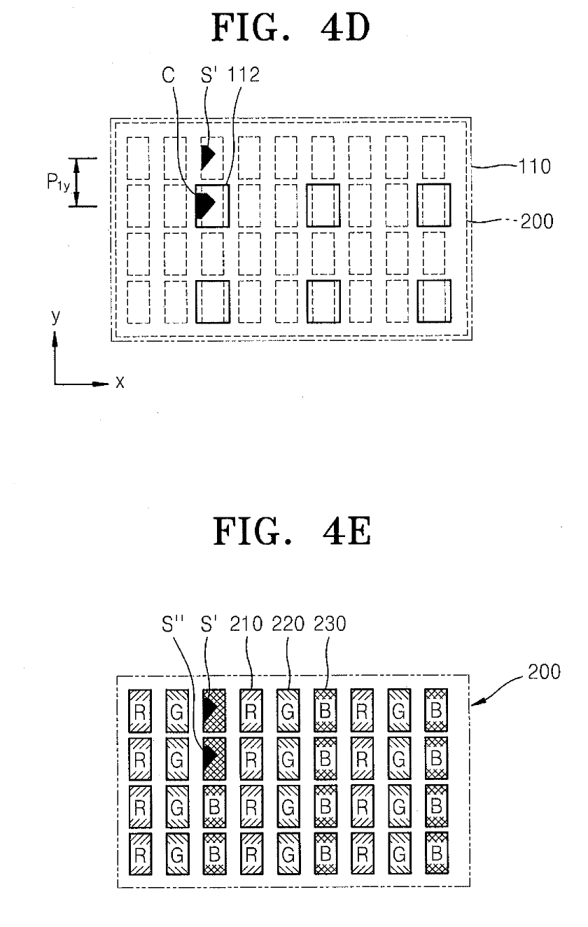

FIGS. 4A-4B illustrate a general method of depositing an organic light emitting layer of an organic EL device using the mask of FIGS. 3A and 3B. Referring to FIG. 4A, a part of an organic EL device is shown in which red (R) and green (G) light emitting layers 210 and 220 are already deposited on an insulating substrate 200 and a blue (B) light emitting layer 230 can be deposited.

In an organic light emitting layer of the organic EL device, unit pixels each combining the red (R), green (G), and blue (B) subpixels are formed in a matrix format. The light emitting layers of the same color are arranged in the same column while the red (R), green (G), and blue (B) light emitting layers are subsequently and alternately arranged in the same row.

Although not illustrated in detail in the drawing, a first electrode layer of a predetermined pattern is formed on the insulating substrate 200 using ITO and red (R), green (G), and blue (B) organic light emitting layers are deposited on the first electrode layer. Also, when the first electrode layer is operated as an anode, a hole injection layer and a hole transport layer may be further provided between the first electrode and the organic light emitting layer. When the second electrode layer is operated as a cathode, an organic film such as an electron injection layer and an electron transport layer may be formed between the second electrode layer and the organic light emitting layer. The organic film may be deposited using an open mask or a fine metal mask that is used in the present embodiment. Any organic film forming materials that are used for a conventional small molecule organic EL device may be used for the organic layer. The layers are deposited in order of the hole injection layer, the hole transport layer, the light emitting layer, the electron transport layer, and the electron injection layer. The structure of layer deposition may be variously modified.

For an active type organic EL device, a plurality of TFTs are electrically connected to each of the first electrodes. When the deposition of the second electrode layer is completed, the active type organic EL device is sealed using a sealing substrate and a terminal that is externally exposed is connected to a drive circuit device so that the organic EL device is completed.

Although in FIG. 4A the red (R) and green (G) light emitting layers 210 and 220 are already deposited, this is merely for the convenience of explanation and thus the deposition sequence of the organic light emitting layer may be changed.

FIG. 4B illustrates a state in which the unit mask 110 and the insulating substrate 200 including an organic EL device are aligned to each other to first deposit the blue (B) light emitting layer 230. Referring to FIG. 4B, the opening portions 112 of the unit mask 110 are arranged to correspond to the positions of blue subpixels arranged in the odd-numbered rows of subpixels where the blue (B) light emitting layers of the organic EL device are to be formed.

As shown in FIG. 4B, in the state in which the unit mask 110 and the insulating substrate 200 having the organic EL device are aligned to each other, an organic light emitting material is deposited by a deposition source (not shown) on the blue subpixels arranged in the odd-numbered rows of the organic EL device. Although in FIG. 4B, the unit mask 10 is arranged on the substrate 200 having the organic EL device for the convenience of explanation, generally, the deposition source is arranged in the lower portion of a deposition chamber (not shown) and the unit mask 110 is arranged above the deposition source. The insulating substrate 200 having the organic EL device is arranged above the unit mask 110.

The mask 100 for an organic EL device may be contaminated by contaminants in the deposition chamber or other environment in the deposition of the organic light emitting layer. In FIG. 4B, a portion of one of the opening portions 112 of the unit mask 110 is contaminated with a contaminant C. The contaminant C may be transferred to a light emitting layer of the organic EL device in the deposition of the organic light emitting layer.

FIG. 4C illustrates a portion of the insulating substrate 200 in which the organic EL device is formed where the blue (B) light emitting layer 230 arranged in the odd-numbered row is first deposited in the alignment state of FIG. 4B. Referring to FIG. 4B, in the organic EL device, not only the red (R) and green (G) light emitting layers 210 and 220 but also the blue (B) light emitting layer 230 arranged on the odd-numbered row is further deposited. A pattern of the contaminant C is transferred to the blue (B) light emitting layer 230 at a position corresponding to each of the opening portions 112 of the unit mask 110 contaminated with the contaminant C so that a first black spot S′ is generated. The black spot S′ formed on the light emitting layer may deteriorate the display quality or cause irregularity in brightness of the organic EL device.

FIG. 4D illustrates a state in which the unit mask 110 and the insulating substrate 200 including an organic EL device are aligned to each other to deposit the blue (B) light emitting layer 230 excluded from the first deposition. Referring to FIG. 4D, the opening portions 112 of the unit mask 110 are moved vertically, that is, in a direction of −y, by a one-pixel pitch P_{1y} from the state of the first deposition and are arranged to correspond to the positions of the blue subpixels arranged in the even-numbered rows, of the subpixels where the blue light emitting layers of the organic EL deice are to be formed.

The terms such as the even-numbered or odd-numbered row used in the present specification are used as relative concepts for the convenience of explanation. As shown in FIG. 4A or 4C, the even number and the odd number are divided based on the order of the pixels shown in a portion of the organic EL device including a plurality of unit pixels, however the present embodiments are not limited thereto. Thus, the opening portion of the mask for an organic EL device used for the present embodiment is formed to correspond to the positions of subpixels of the same color that are alternately arranged in a row, of the pixels formed in each row of the organic EL device.

The subpixels arranged in the even-numbered row are deposited into a blue light emitting layer by the deposition source in the state in which the unit mask 110 and the insulating substrate 200 are aligned as above. The contaminant C formed in the opening portions 112 in the first deposition operation is not eliminated and may be transferred to the organic EL device in the second deposition operation.

FIG. 4E illustrates a portion of the insulating substrate 200 in which the organic EL device on which the blue light emitting layer 230 arranged in each even-numbered row is second deposited is formed in the alignment state of FIG. 4D. Referring to FIG. 4E, in addition to the blue light emitting layer arranged in each odd-numbered row during the first deposition, a blue light emitting layer is further arranged in each even-numbered row in the organic EL device. A pattern of the contaminant D is transferred to the blue light emitting layer 230 at a position corresponding to the opening portion 112 of the mask contaminated with the contaminant C so that a second black spot S″ is generated.

In a process of continuously depositing organic light emitting layers of the organic EL device in the even-numbered and odd-numbered rows using the mask 100 having the contaminant C, the pattern of the contaminant C is transferred so that the first black spot S′ and the second black spot S″ are formed in the neighboring upper and lower subpixels of the organic EL device.

However, when a defective pixel including a black spot is formed adjacent to the pixels as described above, inferior visibility increases. Thus, when a light emitting layer is deposited using a mask for an organic EL device in the above method, the mask sagging phenomenon and the decrease of aperture ratio may be solved but a defect rate increases due to the inferior visibility.

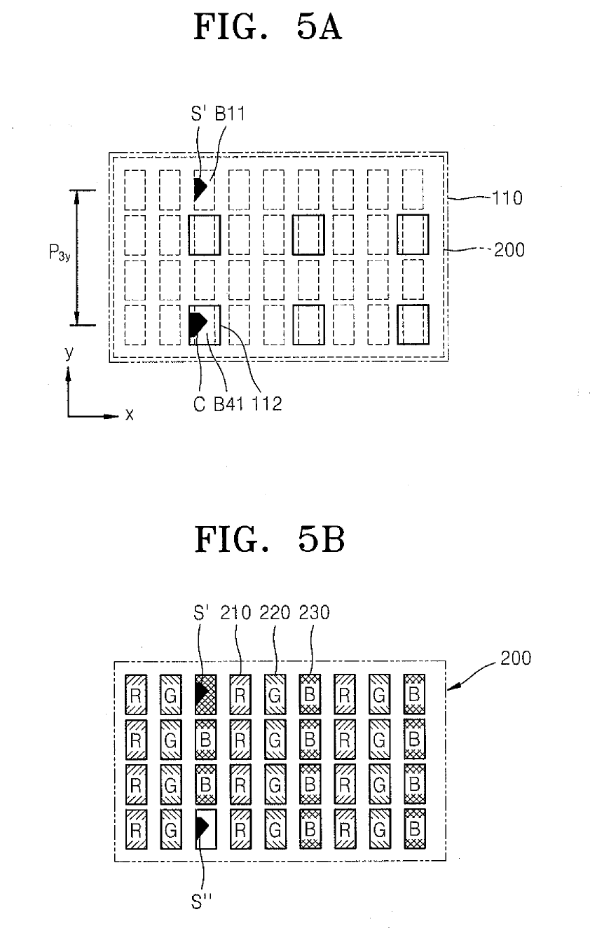

FIGS. 5A and 5B are plan views for explaining a method of depositing an organic light emitting layer of an organic EL device according to an embodiment, to reduce the inferior visibility due to a neighboring black spot. FIG. 5A shows that the insulating substrate 200 including the organic EL device and the unit mask 110 are aligned to each other for the second deposition of the blue light emitting layer in the even-numbered row after the first deposition of the blue light emitting layer in the odd-numbered row is completed.

In the first deposition operation of the blue light emitting layer in the odd-numbered row, since the blue light emitting layer is deposited such that the opening portion 112 of the unit mask 110 having the contaminant C corresponds to a blue subpixel B11 of the unit pixel arranged at the first row and the first column of the organic EL device, the first black spot S′ is formed in the blue subpixel B11 arranged at the first row and the first column.

After the first deposition, the opening portions 112 of the unit mask 110 are moved by a three-pixel pitch P_{3y} vertically with respect to the alignment state of the first deposition, and is aligned to correspond to the positions of the subpixels arranged in the even-numbered row of the subpixels where the blue light emitting layer of the organic EL device is to be formed.

The opening portion 112 of the unit mask 110 having the contaminant C corresponds to a blue subpixel B41 of the unit pixel arranged at the fourth row and the first column. The subpixels arranged in the even-numbered row are second deposited into the blue light emitting layer by the deposition source in the state in which the unit mask 110 and the insulating substrate 200 are aligned as above.

Although it is not illustrated in detail in the drawings, to allow the opening portions 112 of the unit mask 110 to have a structure still corresponding to the blue subpixels in the even-numbered row of the organic EL device after the unit mask 110 is moved by the three-pixel pitch P_{3y} vertically in the direction of −y, the unit mask 110 may include more number of the opening portions 112 than the number of the subpixels around the unit mask 110. The opening portions 112 formed around the unit mask 110 are open and used for the deposition of a pixel when the formation of a pixel is needed. Also, the opening portions 112 may prevent the deposition of a pixel through the opening portion 112 by being blocked by a shield (not shown).

FIG. 5B shows a portion of the insulating substrate 200 on which the organic EL device in which the blue light emitting layer arranged in each even-numbered row is second deposited in the alignment state of FIG. 5A is formed. Referring to FIG. 5B, while the first black spot S′ formed during the first deposition of the blue light emitting layer is formed on the blue subpixel B11 arranged at the first row and the first column, the second black spot S″ formed during the second deposition of the blue light emitting layer is formed on the blue subpixel B41 arranged at the fourth row and the first column. That is, according to the organic deposition method according to the present embodiment, the black spots S′ and S″ generation positions B11 and B41 are located not adjacent to each other but separated from each other. Thus, the inferior visibility is reduced.

In the above embodiment, although the unit mask 110 is moved by the three-pixel pitch P_{3y} vertically in the direction of −y based on the first deposition during the second deposition, the present embodiments are not limited thereto. That is, the unit mask 110 may be moved vertically by a variety of distances, for example, a five-pixel pitch, a seven-pixel pitch, . . . , and a (2N+1) pixel pitch, where N is a natural number. Also, the vertical movement is a relative one so that the unit mask 110 may be moved by a (2N+1) pixel pitch substantially parallelly in a direction of +y.

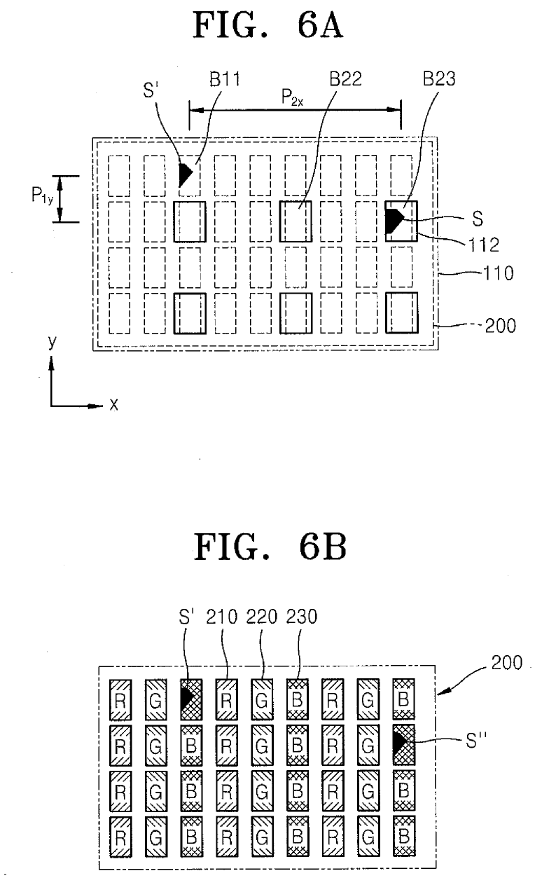

FIGS. 6A and 6B are plan views for explaining a method of depositing an organic light emitting layer of an organic EL device according to another embodiment, to reduce the inferior visibility due to a neighboring black spot. FIG. 6A shows that the insulating substrate 200 including the organic EL device and the unit mask 110 are aligned to each other for the second deposition of the blue light emitting layer in the even-numbered row after the first deposition of the blue light emitting layer in the odd-numbered row is completed.

In the first deposition operation of the blue light emitting layer in the odd-numbered row, since the blue light emitting layer is deposited such that the opening portion 112 of the unit mask 110 having the contaminant C corresponds to the blue subpixel B11 of the unit pixel arranged at the first row and the first column, the first black spot S′ is formed in the blue subpixel B11 arranged at the first row and the first column.

After the first deposition, the opening portions 112 of the unit mask 110 are moved by the one-pixel pitch P_{1y} vertically in the direction of −y and by a two-pixel pitch P₂ₓ in a direction of +x with respect to the alignment state of the first deposition, and is aligned to correspond to the positions of the subpixels arranged in the even-numbered row of the subpixels where the blue light emitting layer of the organic EL device is to be formed.

The opening portion 112 of the unit mask 110 having the contaminant C corresponds to a blue subpixel B23 of the unit pixel arranged at the second row and the third column. The subpixels arranged in the even-numbered row are second deposited into the blue light emitting layer by the deposition source in the state in which the unit mask 110 and the insulating substrate 200 are aligned as above.

Although it is not illustrated in detail in the drawings, to allow the opening portions 112 of the unit mask 110 to have a structure still corresponding to the blue subpixels in the even-numbered row of the organic EL device after the unit mask 110 is moved by the one-pixel pitch P_{1y} vertically in the direction of −y and by the two-pixel pitch P₂ₓ vertically in the direction of +x, the unit mask 110 may include more number of the opening portions 112 than the number of the subpixels around the unit mask 110. The opening portions 112 formed around the unit mask 110 are open and used for the deposition of a pixel when the formation of a pixel is needed. Also, the opening portions 112 may prevent the deposition of a pixel through the opening portion 112 by being blocked by a shield (not shown).

FIG. 6B illustrates a portion of the insulating substrate 200 in which the organic EL device on which the blue light emitting layer 230 arranged in each even-numbered row is second deposited is formed in the alignment state of FIG. 6A. Referring to FIG. 6B, although the first black spot S′ formed during the first deposition of the blue light emitting layer is formed in the blue subpixel B11 of the unit pixel arranged at the first row and the first column, the second black spot S″ formed during the second deposition of the blue light emitting layer is formed in the blue subpixel B23 arranged at the second row and the third column. That is, according to the organic deposition method according to the present embodiment, the black spots S′ and S″ generation positions B 11 and B23 are located not adjacent to each other but separated from each other. Thus, the inferior visibility is reduced.

In the above embodiment, although the unit mask 110 is moved by the one-pixel pitch P_{1y} vertically in the direction of −y and by the two-pixel pitch P₂ₓ horizontally during the second deposition, the present embodiments are not limited thereto. For example, when the unit mask 110 is moved vertically by a one-pixel pitch and horizontally by a one-pixel pitch, the second black spot is formed at a position B22. However, since the second black spot is not adjacent to the first black spot, the inferior visibility is reduced. Accordingly, the present embodiments may be embodied by a combination of moving the mask by an odd-numbered pixel pitch over one pixel pitch (2N−1, N is a natural number) vertically in the direction of −y or +y and moving the mask by a one-pixel or more pitch horizontally in the direction or −x or +x.

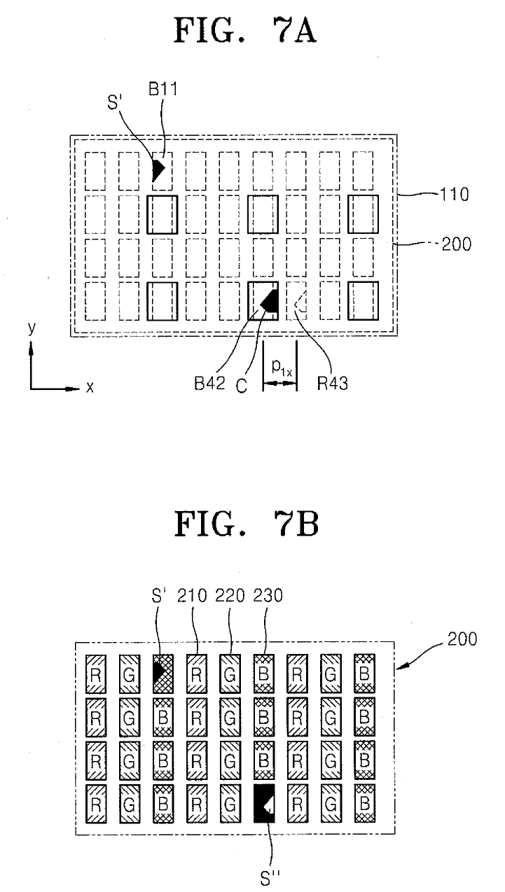

FIGS. 7A and 7B are plan views for explaining a method of depositing an organic light emitting layer of an organic EL device according to another embodiment, to reduce the inferior visibility due to a neighboring black spot. FIG. 7A illustrates that the unit mask 10 and the insulating substrate 200 having an organic EL device are aligned to each other for the second deposition of the blue light emitting layer in the even-numbered row after the first deposition of the blue light emitting layer in the odd-numbered row is completed.

Since, during the first deposition of the blue light emitting layer in the odd-numbered row, the blue light emitting layer is deposited such that the opening portion 112 of the unit mask 110 having the contaminant C corresponds to the blue subpixel B11 arranged at the first row and the first column of the organic EL device, the first black spot S′ is formed at the blue subpixel B11 of the unit pixel arranged at the first row and the first column.

After the first deposition, the opening portions 112 of the unit mask 110 are rotated by 180° around the center of the mask 100 in the alignment state of the first deposition and then moved by a one-subpixel pitch p₁ₓ horizontally in the direction of −x. The one-subpixel pitch equals a ⅓ pixel pitch.

In the present embodiment, it is assumed that the center of the unit mask 110 matches the center of the mask 100 for an organic EL device in FIG. 7A, however the present embodiments are not limited hereto. In this state, the opening portion 112 of the unit mask 110 having the contaminant C corresponds to a red subpixel R43 of a pixel arranged at the fourth row and the third column by the 180° rotation. Next, by moving by the one-subpixel pitch p₁ₓ in the direction of −x, the opening portion 112 of the unit mask 110 having the contaminant C corresponds to the blue pixel B42 of the pixel arranged at the fourth row and the second column. Accordingly, in the state in which the unit mask 110 and the insulating substrate 200 are aligned to each other, the subpixels arranged in the even-numbered row are second deposited by the deposition source into a blue light emitting layer.

In the above-described embodiment, it is assumed that one unit mask is formed on the mask 100 for an organic EL device (please refer to FIG. 3A), however, the present embodiments are not limited thereto. Although the above description focuses on the movement of the unit mask 100 for the convenience of explanation, actual unit masks are subject to the movement of the mask 100 for an organic EL device including the unit masks. Thus, when the mask 100 for an organic EL device including a plurality of unit masks are rotated, the opening portion of the unit mask having a contaminant is positioned in an area of a subpixel of another light emitting device, unlike the illustrations of the drawings. However, in such a case, by moving the unit mask 100 by the one-subpixel pitch in the direction of −x, the opening portion of the unit mask having a contaminant corresponds to a blue pixel arranged in another even-numbered row.

FIG. 7B illustrates a portion of the insulating substrate 200 in which the organic EL device on which the blue light emitting layer 230 arranged in each even-numbered row is second deposited is formed in the alignment state of FIG. 7A. Referring to FIG. 7B, although the first black spot S′ formed during the first deposition of the blue light emitting layer is formed in the blue subpixel B11 of the unit pixel arranged at the first row and the first column, the second black spot S″ formed during the second deposition of the blue light emitting layer is formed in the blue subpixel B42 arranged at the fourth row and the second column. That is, according to the organic deposition method according to the present embodiment, the black spots S′ and S″ generation positions B11 and B42 are located not adjacent to each other but separated from each other. Thus, the inferior visibility is reduced.

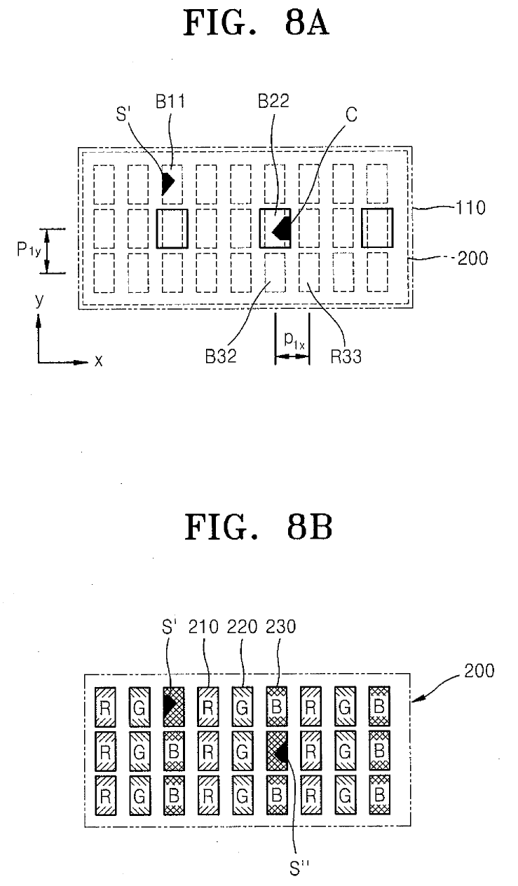

FIGS. 8A and 8B are plan views for explaining a method of depositing an organic light emitting layer of an organic EL device according to a modified example of the embodiment of FIGS. 7A and 7B, to reduce the inferior visibility due to a neighboring black spot. In the embodiment of FIGS. 7A and 7B, when the opening portions 112 having the contaminant C are rotated by 180° around the mask 100 and pixels of an even-numbered row, for example, two rows in the present embodiment, are arranged between the opening portions 112 having the contaminant C before and after the 180° rotation, a blue subpixel in the even-numbered row is the position where the opening portions 112 are horizontally moved by the one-pixel pitch after the rotation.

However, when the opening portions 112 having the contaminant C are rotated by 180° around the mask 100 and pixels of an odd-numbered row, for example, one row, are arranged between the opening portions 112 having the contaminant C before and after the 180° rotation, the position where the opening portions 112 are horizontally moved by the one-pixel pitch after the rotation is a blue subpixel in the odd-numbered row so that the opening portions 112 needs to be further moved by the one-pixel pitch vertically.

FIG. 8A illustrates that the unit mask 110 and the insulating substrate 200 having an organic EL device are aligned to each other for the second deposition of the blue light emitting layer in the even-numbered row after the first deposition of the blue light emitting layer in the odd-numbered row is completed. Since, during the first deposition of the blue light emitting layer in the odd-numbered row, the blue light emitting layer is deposited such that the opening portion 112 of the unit mask 110 having the contaminant C corresponds to the blue subpixel B11 arranged at the first row and the first column of the organic EL device, the first black spot S′ is formed at the blue subpixel B11 of the unit pixel arranged at the first row and the first column.

After the first deposition, the opening portions 112 of the unit mask 110 are rotated by about 180° around the center of the mask 100 in the alignment state of the first deposition and then moved by the one-subpixel pitch pix horizontally in the direction of −x. The one-subpixel pitch equals a ⅓ pixel pitch.

In the present embodiment, it is assumed that the center of the unit mask 110 matches the center of the mask 100 for an organic EL device in FIG. 8A. In this state, the opening portion 112 of the unit mask 110 having the contaminant C corresponds to a red subpixel R33 of a pixel arranged at the third row and the third column by the 180° rotation. Next, by being moved by a one-subpixel pitch in the direction of −x, the opening portion 112 of the unit mask 110 having the contaminant C corresponds to the blue pixel B32 of the pixel arranged at the third row and the second column. In the present embodiment, however, since the blue pixel B32 is a blue light emitting layer arranged in an odd-numbered row, the mask is further moved by the one-pixel pitch Ply vertically in the direction of +y to arrive at the blue subpixel B22 at the second row and the second column. Also, although it is not illustrated in the drawing, the mask may be further moved by the one-pixel pitch in the direction of −y.

FIG. 8B illustrates a portion of the insulating substrate 200 in which the organic EL device on which the blue light emitting layer 230 arranged in each even-numbered row is second deposited is formed in the alignment state of FIG. 8A. Referring to FIG. 8B, although the first black spot S′ formed during the first deposition of the blue light emitting layer is formed in the blue subpixel B11 of the unit pixel arranged at the first row and the first column, the second black spot S″ formed during the second deposition of the blue light emitting layer is formed in the blue subpixel B22 arranged at the second row and the second column. That is, according to the organic deposition method according to the present embodiment, the black spots S′ and S″ generation positions B11 and B22 are located not adjacent to each other but separated from each other. Thus, the inferior visibility is reduced.

As described above, according to the method of depositing a light emitting layer using a mask for an organic EL device according to the present embodiments, the mask sagging and the opening portion reduction are prevented and the inferior visibility due to the generation of a neighboring black spot may be reduced.

The embodiments may, however, be embodied in many different forms and should not be construed as being limited to the embodiments set forth herein; rather, these embodiments are provided so that this disclosure will be thorough and complete, and will fully convey the concept of the embodiments to those skilled in the art. While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A method of depositing a light emitting layer of an organic EL device in which a subpixel combination having a plurality of different colors is set as a unit pixel, a plurality of subpixels are sequentially and alternately arranged in a row direction, and a plurality of subpixels of the same color are arranged in a column direction, the method comprising:
depositing the light emitting layer using a mask having a plurality of opening portions corresponding to positions of the subpixels of the same color arranged in any of an odd-numbered row and an even-numbered row of the subpixles; and
depositing the light emitting layer by moving the mask to prevent the light emitting layer from being deposited at a subpixel adjacent to the subpixel where the light emitting layer is deposited during the first deposition operation, using the same opening portion of the mask used for the first deposition operation of the light emitting layer.

2. The method of claim 1, wherein the subpixels comprise different colors comprising at least one of red (R), green (G), and blue (B) subpixels.

3. The method of claim 1, wherein the second deposition operation is performed by moving the mask aligned in the first deposition operation in the column direction by a (2N+1) pixel pitch or more, wherein N is a natural number.

4. The method of claim 1, wherein the second deposition operation is performed by moving the mask aligned in the first deposition operation by a (2N−1) pixel pitch or more in the column direction, and by an N-pixel pitch or more in the row direction, wherein N is a natural number.

5. The method of claim 1, wherein the second deposition operation is performed by rotating the mask aligned in the first deposition operation by 180° and moving the mask by a one-pixel pitch in the row direction.

6. The method of claim 1, wherein the second deposition operation is performed by rotating the mask aligned in the first deposition operation by 180° and moving the mask by a one-pixel pitch horizontally in the row direction and by a one-pixel pitch vertically in the column direction.

7. The method of claim 1, wherein the mask having the opening portions is used for independently depositing each of the subpixels of different colors.

8. The method of claim 1, wherein the mask having the opening portions is a fine metal mask.

9. A method of manufacturing an organic EL device, the method comprising:
forming a first electrode layer of a predetermined pattern on an insulating substrate;
forming an organic light emitting layer comprising a light emitting layer of a predetermined pattern on the first electrode layer;
forming a second electrode layer of a predetermined pattern on the organic light emitting layer; and
sealing the outside of the second electrode layer,
wherein, in the organic EL device in which a subpixel combination having a plurality of different colors is set as a unit pixel, a plurality of subpixels are sequentially and alternately arranged in a row direction, and a plurality of subpixels of the same color are arranged in a column direction,
wherein forming the organic light emitting layer comprises:
depositing the light emitting layer using a mask having a plurality of opening portions corresponding to positions of the subpixels of the same color arranged in any of an odd-numbered row and an even-numbered row of the subpixles; and
depositing the light emitting layer by moving the mask to prevent the light emitting layer from being deposited at a subpixel adjacent to the subpixel where the light emitting layer is deposited during the first deposition operation, using the same opening portion of the mask used for the first deposition operation of the light emitting layer.

10. The method of claim 9, wherein the subpixels having different colors comprise red (R), green (G), and blue (B) subpixels.

11. The method of claim 9, wherein the second deposition operation is performed by moving the mask aligned in the first deposition operation by a (2N+1) pixel pitch or more in the column direction, where N is a natural number.

12. The method of claim 9, wherein the second deposition operation is performed by moving the mask aligned in the first deposition operation by a (2N−1) pixel pitch or more in the column direction, where N is a natural number and by an N-pixel pitch or more in the row direction, where N is a natural number.

13. The method of claim 9, wherein the second deposition operation is performed by rotating the mask aligned in the first deposition operation by 180° and moving the mask by a one-pixel pitch in the row direction.

14. The method of claim 9, wherein the second deposition operation is performed by rotating the mask aligned in the first deposition operation by 180° and moving the mask by a one-pixel pitch horizontally in the row direction, and by a one-pixel pitch vertically in the column direction.

15. The method of claim 9, wherein the mask having the opening portions is used for independently depositing the subpixels of different colors.

16. An organic EL device manufactured by a method of claim 9.

17. An organic EL device manufactured by a method of claim 10.

18. An organic EL device manufactured by a method of claim 11.

19. An organic EL device manufactured by a method of claim 12.

20. An organic EL device manufactured by a method of claim 13.

21. An organic EL device manufactured by a method of claim 14.

22. An organic EL device manufactured by a method of claim 15.
